(19) United States
(12) Patent Application Publication
(10) Pub. No.: US 2021/0408487 A1
(43) Pub. Date: Dec. 30, 2021

(54) DISPLAY PANEL, MANUFACTURING METHOD THEREOF, AND DISPLAY DEVICE

(71) Applicant: WUHAN CHINA STAR OPTOELECTRONICS SEMICONDUCTOR DISPLAY TECHNOLOGY CO., LTD, Wuhan (CN)

(72) Inventors: Wenliang GONG, Wuhan (CN); Wenxu XIANYU, Wuhan (CN)

(73) Assignee: WUHAN CHINA STAR OPTOELECTRONICS SEMICONDUCTOR DISPLAY TECHNOLOGY CO., LTD, Wuhan (CN)

(21) Appl. No.: 16/637,769

(22) PCT Filed: Dec. 12, 2019
(86) PCT No.: PCT/CN2019/124869

§ 371 Date: Feb. 10, 2020

(30) Foreign Application Priority Data
Nov. 6, 2019 (CN) 201911078336.9

(51) Int. Cl. H01L 51/52; H01L 27/32; H01L 51/56

(52) U.S. Cl. CPC H01L 51/5268; H01L 27/322; H01L 2251/558; H01L 2251/303; H01L 2251/5369; H01L 51/56

(57) ABSTRACT

The present invention provides a display panel, a manufacturing method of the display panel, and a display device. The display panel includes a functional layer which is unflattened and contains nano-particles on a color filter substrate. When incident light passes through the functional layer unflattened and containing the nano-particles, the incident light diverges and is scattered. Therefore, ambient light can be scattered effectively. Accordingly, reflectivity of the display panel is lowered, and a contrast ratio of the display panel is improved.

This application claims priority to Chinese patent application no. 201911078336.9, entitled “Display Panel, Manufacturing Method thereof, and Display device”, filed on Nov. 6, 2019, and the entire contents of which are incorporated by reference in this application.

### 1. Field of Disclosure

The present invention relates to a field of display devices and in particular, to a display panel, a manufacturing method thereof, and a display device.

### 2. Description of Related Art

Currently, organic light-emitting diodes (OLEDs) have advantages of excellent display performance, being self-luminous, a simple structure, being ultra-thin and light, fast response speed, wide viewing angles, low power consumption, and flexible display.

The light emission principle of OLED is that, an organic semiconductor materials and a light-emitting material is driven by an electric field to cause light emission through carrier injection and recombination. Specifically, OLED display devices usually use ITO pixel electrodes and metal electrodes as anodes and cathodes, respectively. Driven by a certain voltage, electrons and holes are respectively transferred into an electron transport layer and a hole transport layer from the cathode and the anode. The electrons and the holes are respectively transferred through the electron transport layer and the hole transport layer to the light-emitting layer, the electrons and the holes meet in the light-emitting layer to form excitons and excite light-emitting molecules, and the light-emitting molecules emit visible light after radiation relaxation.

With the development of organic light-emitting diode (OLED) technology, there has been a trend toward reducing thicknesses of films of flexible displays. Accordingly, a color filter is used to replace a polarizer, thereby greatly improving a light transmittance of the OLED and greatly reducing a thickness of a panel module, thus getting attention and being used extensively in cutting-edge flexible displays. However, reflectivity of the color filter is inferior to reflectivity of the polarizer, resulting in poor display quality of the OLED.

### SUMMARY

The present invention provides a display panel. Compared with conventional techniques, the present application adds a functional layer on a color filter substrate. The functional layer is unflattened and contains nano-particles. In the structure, incident light diverges and is scattered when passing through the functional layer which is unflattened and contains the nano-particles. Therefore, ambient light can be effectively scattered, thereby lowering reflectivity of the display panel and improving a contrast ratio of the display panel.

Accordingly, in one aspect, the present application provides a display panel, comprising a display plate, an encapsulation layer, a color filter substrate, and a functional layer unflattened and containing nano-particles, wherein the encapsulation layer is disposed on the display plate, the color filter substrate is disposed on the encapsulation layer, and the functional layer unflattened and containing the nano-particles is disposed on the color filter substrate.

The nano-particles are composed of a colorless and transparent nano-particle material.

The nano-particles are SiO₂ or TiO₂.

A mass ratio of the nano-particles ranges from 1% to 10%.

A diameter of the nano-particle ranges from 100 nm to 200 nm.

A thickness of the functional layer ranges from 0.5 um to 1.5 um.

Accordingly, in another aspect, the present application provides a manufacturing method of a display panel, comprising following steps:

providing a display plate;

forming an encapsulation layer on the display plate;

forming a color filter substrate on the encapsulation layer; and

forming a functional layer unflattened and containing nano-particles on the color filter substrate.

The step of forming the functional layer unflattened and containing the nano-particles on the color filter substrate comprises:

coating the color filter substrate with an organic photoresist containing the nano-particles to form an organic photoresist layer containing the nano-particles;

curing the organic photoresist layer; and

forming the functional layer unflattened and containing the nano-particles by plasma etching the cured organic photoresist layer.

The organic photoresist is made of a transparent organic photoresist material.

The organic photoresist is made of acrylic or methacrylic polymer.

The present application further provides a display device. The display device comprises a display panel. The display panel comprises a display plate, an encapsulation layer, a color filter substrate, and a functional layer which is unflattened and contains nano-particles, wherein the encapsulation layer is disposed on the display plate, the color filter substrate is disposed on the encapsulation layer, and the functional layer unflattened and containing the nano-particles is disposed on the color filter substrate.

The nano-particles are composed of a colorless and transparent nano-particle material.

The nano-particles are SiO₂ or TiO₂.

A mass ratio of the nano-particles ranges from 1% to 10%.

A diameter of the nano-particle ranges from 100 nm to 200 nm.

A thickness of the functional layer ranges from 0.5 um to 1.5 um.

The present invention provides a display panel. The display panel comprises a display plate, an encapsulation layer, a color filter substrate, and a functional layer which is unflattened and contains nano-particles. The encapsulation layer is disposed on the display plate, the color filter substrate is disposed on the encapsulation layer, and the functional layer is disposed on the color filter substrate. Compared with conventional technology, the present application adds the functional layer, unflattened and containing the nano-particles, on the color filter substrate. Therefore, when incident light passes through the functional layer unflattened and containing the nano-particles, the incident light diverges and is scattered, so ambient light can be scattered effectively. Accordingly, reflectivity of the display panel is lowered, and a contrast ratio of the display panel is improved.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work.

FIG. 1 is a schematic structural view illustrating a display panel according to one embodiment of the present invention;

FIG. 2 is a schematic structural view illustrating the display panel according to another embodiment of the present invention;

FIG. 3 is a process flow diagram illustrating a manufacturing method of the display panel according to one embodiment of the present invention;

FIG. 4 is a process flow diagram illustrating the manufacturing method of the display panel according to another embodiment of the present invention; and

FIG. 5 is a process flow diagram illustrating the manufacturing method of the display panel according to another embodiment of the present invention.

### DETAILED DESCRIPTION OF EMBODIMENTS

The technical solutions of the embodiments of the present invention will be clearly and completely described below with reference to the accompanying drawings. It is apparent that the embodiments are only some embodiments of the present invention, and not all of the embodiments. All other embodiments obtained by those skilled in the art based on the embodiments of the present disclosure without an inventive step are deemed to be within the protection scope of the present invention.

In the present disclosure, it should be understood that the terms, such as “central”, “longitudinal”, “lateral”, “length”, “width”, “thickness”, “up”, “down”, “front”, “rear”, “left”, “right”, “vertical”, “horizontal”, “top”, “bottom”, “inside”, and “outside”, indicate orientations or positional relationships based on the drawings, and are only for ease of the description. These directional terms are not intended to indicate or imply the device or element referred to must have a specific orientation or be constructed and operated in a specific orientation, and therefore cannot be understood as limitations in this application. In addition, the terms like “first” and “second” are used for illustrative purposes only and cannot be understood as indicating or implying relative importance or implicitly indicating the number of technical features indicated. Therefore, the features defined with “first” and “second” can explicitly or implicitly include one or more of the features. In the present application, “multiple” is two or more, unless it is specifically defined otherwise.

With the development of organic light-emitting diode (OLED) technology, there has been a trend toward reducing thicknesses of films of flexible displays. Accordingly, a color filter is used to replace a polarizer, thereby greatly improving a light transmittance of the OLED and greatly reducing a thickness of a panel module, thus being used extensively in cutting-edge flexible displays. However, reflectivity of the color filter is inferior to reflectivity of the polarizer, resulting in poor display quality of the OLED.

Accordingly, the present invention provides a display panel, a manufacturing method thereof, and a display device which are described in detail below, respectively.

First, the present invention provides a display panel. The display panel comprises a display plate, an encapsulation layer, a color filter substrate, and a functional layer which is unflattened and contains nano-particles. The encapsulation layer is disposed on the display plate, the color filter substrate is disposed on the encapsulation layer, and the functional layer unflattened and containing the nano-particles is disposed on the color filter substrate.

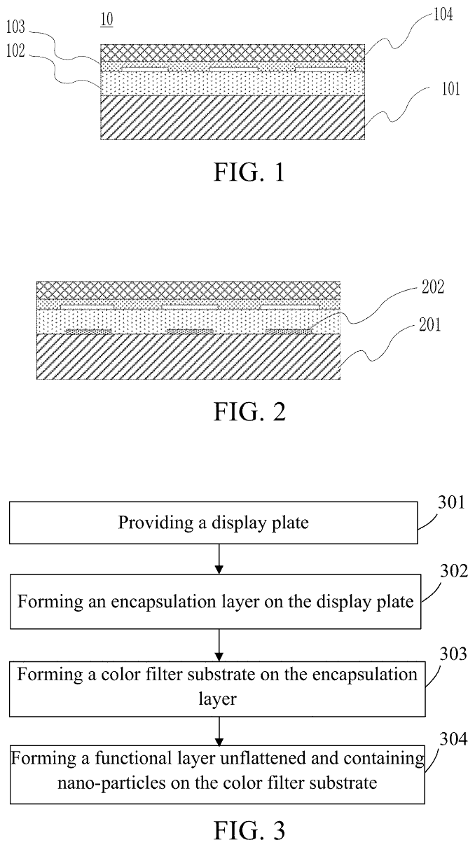

Referring to FIG. 1, it is a schematic structural view illustrating a display panel according to one embodiment of the present invention. The display panel 10 comprises a display plate 101, an encapsulation layer 102, a color filter substrate 103, and a functional layer 104 which is unflattened and contains nano-particles. The encapsulation layer 102 is disposed on the display plate 101, the color filter substrate 103 is disposed on the encapsulation layer 102, and the functional layer 104 unflattened and containing the nano-particles is disposed on the color filter substrate 103.

In summary, the present invention provides a display panel 10. The display panel 10 comprises a display plate 101, an encapsulation layer 102, a color filter substrate 103, and a functional layer 104 unflattened and containing nano-particles. The encapsulation layer 102 is disposed on the display plate 101, the color filter substrate 103 is disposed on the encapsulation layer 102, and the functional layer 104 is disposed on the color filter substrate 103. Compared with conventional technology, the present application adds the functional layer 104, unflattened and containing the nano-particles, on the color filter substrate 103. Therefore, when incident light passes through the functional layer unflattened and containing the nano-particles, the incident light diverges and is scattered, so ambient light can be effectively scattered. Accordingly, reflectivity of the display panel is lowered, and a contrast ratio of the display panel is improved.

In some embodiments of the present application, the nano-particles are composed of a colorless and transparent nano-particle material.

In detail, the present application needs to scatter the ambient light, reduce the reflectivity of the display panel, and improve the contrast ratio of the display panel without affecting a light transmittance of the display panel. Therefore, it is necessary to use the colorless and transparent nano-particles.

In some embodiments of the present application, the nano-particles are made of SiO₂ or TiO₂. The nano-particle material is mainly an inorganic material and is not sensitive to plasma. The nano-particle material is, for example, SiO₂.

Regarding the chemical term “SiO₂”, pure SiO₂ is colorless, solid at room temperatures and insoluble in water. SiO₂ is insoluble in acid, but soluble in hydrofluoric acid and hot concentrated phosphoric acid, and SiO₂ can react with molten alkalis. There are two kinds of SiO₂ in nature, i.e. crystalline silica and amorphous silica. SiO₂ has a wide range of use, mainly used for making glass and sodium silicate.

In some embodiments of the present application, a mass ratio of the nano-particles ranges from 1% to 10%. In detail, in order to provide an anti-reflection function, it is necessary to control a size and a concentration of the nano-particles and the conditions for a plasma treatment. Therefore, the mass ratio of the nano-particles of the present application is 1% to 10%, but the present application is not intended to limit the mass ratio of the nano-particles, and the mass ratio can vary according to requirements.

In some embodiments of the present application, a diameter of the nano-particle ranges from 100 nm to 200 nm.

In some embodiments of the present application, the organic photoresist is made of a transparent organic photoresist material.

Specifically, the present invention needs to scatter the ambient light, reduce the reflectivity of the display panel, and increase the contrast ratio of the display panel without affecting the light transmittance of the display panel. Therefore, it is necessary to use the organic photoresist with a high light transmittance for visible light and is colorless and transparent.

In some embodiments of the present application, the organic photoresist is acrylic or methacrylic polymer. However, the material of the organic photoresist is not limited by the present application, and the organic photoresist can be other suitable material according to actual requirement.

In some embodiments of the present application, a thickness of the functional layer ranges from 0.5 um to 1.5 um. For example, the thickness of the functional layer is 0.8 um. The thickness of the functional layer is not limited in this application, and the thickness of the functional layer may vary according to actual requirement.

The present application further provides a manufacturing method of a display panel, comprising following steps:

providing a display plate, wherein the display plate comprises a display region;

forming an encapsulation layer on the display plate;

forming a color filter substrate on the encapsulation layer, wherein the color filter substrate is arranged corresponding to the display region; and

forming a functional layer unflattened and containing nano-particles on the color filter substrate.

Referring to FIG. 3, it is a process flow diagram illustrating a manufacturing method of a display panel according to one embodiment of the present invention. The manufacturing method comprises:

Step 301: providing a display plate.

Referring to FIG. 2, it is a schematic structural view illustrating the display panel according to another embodiment of the present invention. The display plate 101 comprises an array substrate 201 and a light-emitting device 202. The light-emitting device 202 includes an anode, a hole transport layer, a light-emitting layer, an electron transport layer, and a cathode.

Step 302: forming an encapsulation layer on the display plate.

The encapsulation layer can use cover plate encapsulation technology or thin film encapsulation technology. The present application is not intended to limit the encapsulation technology used in the present application, and encapsulation methods may vary as required.

Specifically, the cover plate encapsulation is generally used for an OLED device with a rigid substrate such as a glass substrate. A substrate of the OLED device is transferred into a glove box from a chamber of an OLED system. An inert gas environment in the glove box requires water and oxygen below 1 ppm. Then, the cover plate is transferred from the chamber to a plasma processing cavity for performing a PT treatment on the cover plate, so that a surface of the cover plate is activated, and thereby an epoxy ultraviolet (UV) curable adhesive has good wettability on the surface and is tightly connected to it. The cover plate is transferred to the glove box after the PT treatment, then a desiccant is attached to absorb the encapsulation, and after that, the water generated during the steps for the OLED device may remain in a sealed space after the encapsulation is absorbed. Then, a coating machine with set up programs adjusting a width of the

UV curable adhesive is used to complete applying the epoxy UV curable adhesive. Both the substrate and the cover plate are put into a vacuum chamber, then they are bonded together under a vacuum environment, and they are finally put into an ultraviolet exposure machine and exposed and heat-cured at about 60° C. This way, organic functional layers and electrodes sandwiched between the cover plate and the substrate are sealed to be isolated from water, oxygen, and ash in the surroundings and to prevent the functional layers of the OLED device from reacting with the water and oxygen in the air.

Step 303: forming a color filter substrate on the encapsulation layer.

The color filter substrate comprises a glass substrate, a black matrix, and red/green/blue (three primary colors) color resists. The red/green/blue color resists are arranged corresponding to sub-pixels of pixels of the light-emitting device. That is to say, the red color resist is arranged corresponding to the red sub-pixel, and the black matrix is arranged between adjacent color resists. The black matrix is used to block scattered light, prevent color mixing between the sub-pixels, and prevent a part of the spectrum of natural light to form a primary color in the mixed color through a matching monochromatic spectrum.

Step 304: forming a functional layer unflattened and containing nano-particles on the color filter substrate.

The present invention provides a manufacturing method of a display panel. The display panel comprises a display plate, an encapsulation layer, a color filter substrate, and a functional layer which is unflattened and contains nano-particles. The encapsulation layer is disposed on the display plate, the color filter substrate is disposed on the encapsulation layer, and the functional layer unflattened and containing the nano-particles is disposed on the color filter substrate.

Compared with conventional technology, the present application adds the functional layer, unflattened and containing the nano-particles, on the color filter substrate. Therefore, when incident light passes through the functional layer unflattened and containing the nano-particles, the incident light diverges and is scattered, so ambient light can be scattered effectively. Accordingly, reflectivity of the display panel is lowered, and a contrast ratio of the display panel is improved.

In some embodiments of the present application, the step of forming the functional layer unflattened and containing the nano-particles on the color filter substrate comprises: coating the color filter substrate with an organic photoresist containing the nano-particles to form an organic photoresist layer containing the nano-particles; curing the organic photoresist layer; and forming the functional layer unflattened and containing the nano-particles by plasma etching the cured organic photoresist layer.

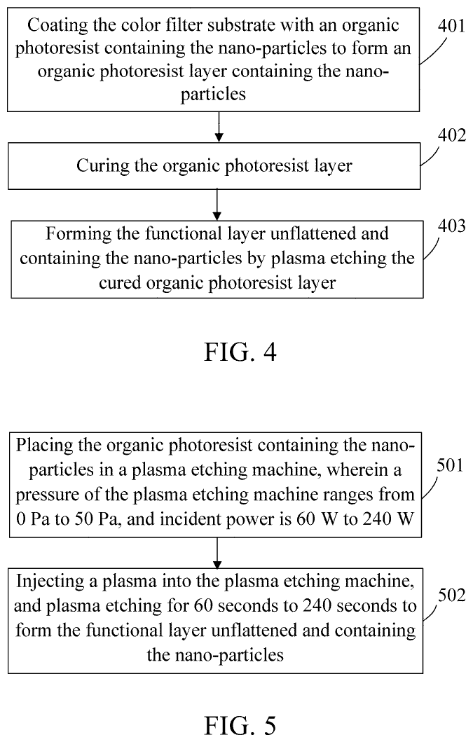

Referring to FIG. 4, it is a process flow diagram illustrating a manufacturing method of a display panel according to another embodiment of the present invention. The step of forming the functional layer unflattened and containing the nano-particles on the color filter substrate comprises:

Step 401: coating the color filter substrate with an organic photoresist containing the nano-particles to form an organic photoresist layer containing the nano-particles.

Specifically, the nano-particles are dispersed in a polymerizable photosensitive or a heat-sensitive liquid, so that they are mixed uniformly without precipitation. The nano-particle material is mainly an inorganic material and is not sensitive to plasma, and the nano-particle material is, for example, SiO₂ or TiO2. A particle size ranges from 100 nm to 200 nm. The polymerizable material is mainly photosensitive or heat-sensitive acrylic or methacrylic polymerized monomers and prepolymers.

The color filter substrate is coated with the organic photoresist containing the nano-particles in a thickness of 0.5 um to 1.5 um.

Step 402: curing the organic photoresist layer.

Specifically, the material just applied to the color filter substrate is still in a non-solid state, so the material needs to be cured to turn into a fixed form to facilitate subsequent steps.

For the heat-sensitive type, films are completely cured and formed by heating; for the photosensitive type, films are cured and formed by radiation of ultraviolet light. Parameters such as a coating thickness and baking temperatures can be adjusted according to specific requirement.

The present application is not limited in this regard, and configurations may vary according to requirement.

In some embodiments of the present application, the step of curing the organic photoresist layer which comprises the nano-particles comprises:

The organic photoresist layer containing the nano-particles is heated or irradiated by ultraviolet light to cure the organic photoresist layer which contains the nano-particles. The present application is not intended to limit the said curing method, and the curing method may vary as required.

Step 403: forming the functional layer unflattened and containing the nano-particles by plasma etching the cured organic photoresist layer.

The plasma has a strong ability to etch the organic photoresist, but cannot etch most inorganic materials.

In some embodiments of the present application, the step of forming the functional layer unflattened and containing the nano-particles by plasma etching the cured organic photoresist layer comprises: placing the organic photoresist containing the nano-particles in a plasma etching machine, wherein a pressure of the plasma etching machine ranges from 0 Pa to 50 Pa, and incident power is 60 W to 240 W; and injecting a plasma into the plasma etching machine, and plasma etching for 60 seconds to 240 seconds to form the functional layer unflattened and containing the nano-particles.

Referring to FIG. 5, it is a process flow diagram illustrating the manufacturing method of the display panel according to another embodiment of the present invention. The step of forming the functional layer unflattened and containing the nano-particles by plasma etching the cured organic photoresist layer comprises:

Step 501: placing the organic photoresist containing the nano-particles in a plasma etching machine, wherein a pressure of the plasma etching machine ranges from 0 Pa to 50 Pa, and incident power is 60 W to 240 W.

Specifically, the plasma etching machine is also called a plasma plane etching machine, a plasma etch machine, a plasma surface treatment instrument, a plasma cleaning system, and the like. Plasma etching is the most common type of dry etching. The principle is that a gas exposed in an electron region forms a plasma, resulting in an ionized gas and a gas that releases high-energy electrons, thus forming the plasma or ions. When atoms of the ionized gas are accelerated by an electric field, a sufficiently large force is released and collaborates with a surface repelling force to tightly bond a material or etch a surface. Generally speaking, plasma cleaning is substantially a milder case of plasma etching. The equipment for performing the dry etching process includes a reaction chamber, a power source, and a vacuum section. A workpiece is fed into the reaction chamber evacuated by a vacuum pump. The gas is introduced and exchanged with the plasma. The plasma reacts on a surface of the workpiece, and volatile byproducts of the reaction are pumped away by the vacuum pump. The plasma etching process is actually a reactive plasma process.

Step 502: injecting a plasma into the plasma etching machine, and plasma etching for 60 seconds to 240 seconds to form the functional layer unflattened and containing the nano-particles.

In some embodiments of the present application, the plasma comprises O₂ and Ar. O₂ is a main plasma material. Ar is an inert gas, and Ar is used to dilute O₂. The material of the plasma is not limited by the present application, and the material of the plasma may vary according to actual situations.

In some embodiments of the present application, a volume ratio of O₂ to the plasma is 5% to 50%. For example, the volume ratio of O₂ to the plasma is 15%. The present application is not intended to limit the volume ratio of O₂ to the plasma; the volume ration may vary according to actual situations.

In order to better implement the display panel of the present invention, the present invention further provides a display device based on the display panel. The display device comprises the display panel of any one of the foregoing embodiments.

The present invention provides a display panel. The display panel comprises a display plate, an encapsulation layer, a color filter substrate, and a functional layer unflattened and containing nano-particles. The encapsulation layer is disposed on the display plate, the color filter substrate is disposed on the encapsulation layer, and the functional layer unflattened and containing the nano-particles is disposed on the color filter substrate. Compared with conventional techniques, the application adds a functional layer, unflattened and containing the nano-particles, on the color filter substrate. When incident light passes through the functional layer unflattened and containing the nano-particles, the incident light diverges and is scattered, so ambient light can be scattered effectively. Accordingly, reflectivity of the display panel is lowered, a contrast ratio of the display panel is improved, and display performance of the display device is improved.

In the above embodiments, the description of each embodiment has its own emphasis. For those not described in detail in one embodiment, please refer to the detailed descriptions in other embodiments above, and the detailed descriptions will not be repeated here.

In practice, the above units or structures may be implemented as independent entities, or may be combined to be one or several entities. For the specific implementation of the above units or structures, please refer to the foregoing embodiments, detailed descriptions of the embodiments are not repeated here.

For specific steps, please refer to the foregoing embodiments, and details are not described herein again.

The present invention provides a display panel, a manufacturing method thereof, and a display device. Specific examples are used to explain the principles and embodiments of the present invention. The description of the above embodiments is only for ease of understanding of the present invention. Modifications and changes can be made by persons of ordinary skill in the art based on the ideas of the present application. Accordingly, the content of the present disclosure should not be construed as a limitation in the present application.

What is claimed is:

1. A display panel, comprising:
a display plate;
an encapsulation layer;
a color filter substrate; and
a functional layer unflattened and containing nano-particles, wherein the encapsulation layer is disposed on the display plate, the color filter substrate is disposed on the encapsulation layer, and the functional layer unflattened and containing the nano-particles is disposed on the color filter substrate.

2. The display panel according to claim 1, wherein the nano-particles are composed of a colorless and transparent nano-particle material.

3. The display panel according to claim 1, wherein the nano-particles are SiO₂ or TiO₂.

4. The display panel according to claim 1, wherein a mass ratio of the nano-particles ranges from 1% to 10%.

5. The display panel according to claim 1, wherein a diameter of the nano-particle ranges from 100 nm to 200 nm.

6. The display panel according to claim 1, wherein a thickness of the functional layer ranges from 0.5 um to 1.5 um.

7. A manufacturing method of a display panel, comprising following steps:
providing a display plate;
forming an encapsulation layer on the display plate;
forming a color filter substrate on the encapsulation layer; and
forming a functional layer unflattened and containing nano-particles on the color filter substrate.

8. The manufacturing method of the display panel according to claim 7, wherein the step of forming the functional layer unflattened and containing the nano-particles on the color filter substrate comprises:
coating the color filter substrate with an organic photoresist containing the nano-particles to form an organic photoresist layer containing the nano-particles;
curing the organic photoresist layer; and
forming the functional layer unflattened and containing the nano-particles by plasma etching the cured organic photoresist layer.

9. The manufacturing method of the display panel according to claim 8, wherein the organic photoresist is made of a transparent organic photoresist material.

10. A display device comprising a display panel, the display panel comprising:
a display plate;
an encapsulation layer;
a color filter substrate; and
a functional layer unflattened and containing nano-particles, wherein the encapsulation layer is disposed on the display plate, the color filter substrate is disposed on the encapsulation layer, and the functional layer unflattened and containing the nano-particles is disposed on the color filter substrate.

11. The display device according to claim 10, wherein the nano-particles are composed of a colorless and transparent nano-particle material.

12. The display device according to claim 10, wherein the nano-particles are SiO₂ or TiO₂.

13. The display device according to claim 10, wherein a mass ratio of the nano-particles ranges from 1% to 10%.

14. The display device according to claim 10, wherein a diameter of the nano-particle ranges from 100 nm to 200 nm.

15. The display device according to claim 10, wherein a thickness of the functional layer ranges from 0.5 um to 1.5 um.
